(19) United States
(12) Patent Application Publication
(10) Pub. No.: US 2013/0170307 A1
(43) Pub. Date: Jul. 4, 2013

(54) ELECTRONIC DEVICE AND METHOD FOR TESTING ENDURANCE OF MEMORY

(71) Applicant: MIN TAN, Shenzhen City (CN)

(72) Inventor: MIN TAN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/559,567

(22) Filed: Jul. 26, 2012

(30) Foreign Application Priority Data
Dec. 30, 2011 (CN) 201110451947.0

(51) Int. Cl. G11C 29/00

(52) U.S. Cl. 365/201

(57) ABSTRACT

An electronic device for endurance test of a memory includes an interface, a storage unit, an obtaining unit, and a control unit. The interface is for connecting the memory to the electronic device. The storage unit stores a variety of test packages for different storage capacities of memories and at least one test option associated with each test package. The test option defines a predetermined capacity of the associated memory to be tested. The obtaining unit obtains a storage capacity of the memory connected to the electronic device. The control unit selects one of the at least one test option associated with one of the test packages corresponding to the obtained storage capacity, selects a plurality of blocks according to the predetermined capacity of the selected test option, assigns corresponding logical addresses to the selected blocks, and then tests the endurance of the selected blocks.

### BACKGROUND

1. Technical Field

The present disclosure relates to electronic devices and, more particularly, to an electronic device for testing endurance of a memory and a method adapted for the electronic device.

2. Description of Related Art

Memories such as hard disks need to pass an endurance test before being put on the market. The endurance test involves actions such as repeatedly writing data into the hard disks and then deleting the data from the hard disk to test the ability of the hard disk to withstand repeated programming and erasing cycles (P/E cycles).

However, in order to improve the endurance of the hard disk, the P/E cycles are implemented sometimes up to 10,000,000,000 times or even more, and such mass number of cycle times thus prolongs the testing time of the endurance test of the hard disk.

Therefore, what is needed is a means to solve the problem described above.

### BRIEF DESCRIPTION OF THE DRAWINGS

Many aspects of the present disclosure should be better understood with reference to the following drawings. The units in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a block diagram of an electronic device for testing endurance of a memory, in accordance with an exemplary embodiment.

FIG. 2 is a flowchart of a method for testing endurance of a memory, in accordance with an exemplary embodiment.

### DETAILED DESCRIPTION

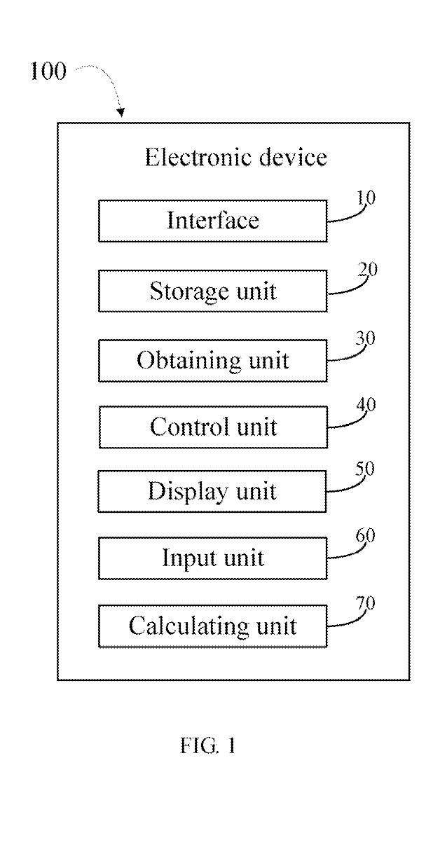

FIG. 1 is a block diagram of an electronic device 100, according to an exemplary embodiment. The electronic device 100, such as a computer or a server, is configured for testing endurance of a memory 200. The memory 200, such as a hard disk, includes a number of blocks. When one block is assigned a logical address, the electronic device 100 can write programs into the block and erase the programs from the block according to the assigned logical address, thus the P/E cycles can be done to test the endurance of the memory 200. In the embodiment, the electronic device 100 includes an interface 10, a storage unit 20, an obtaining unit 30, and a control unit 40.

The interface 10 connects the memory 200 to the electronic device 100.

The storage unit 20 stores a variety of test packages for different storage capacities of memories 200 and at least one test option associated with each test package, and the test option defines a predetermined capacity of the associated memory 200 to be tested. Take a hard disk having 2 megabytes of storage capacity for an example, almost 250,000 blocks are included. Two test options are stored in the storage unit 20 associated with the test package of 2 megabytes, for example, a first test option corresponding to a selection of 0.5 megabytes of the memory 200, and a second test option corresponding to a selection of 1 megabyte of the memory 200.

The obtaining unit 30 obtains the storage capacity of the memory 200 connected to the electronic device 100 via the interface 10.

The control unit 40 determines the at least one associated test option of the test package corresponding to the obtained storage capacity. If the test package corresponding to the obtained storage capacity associates only one test option, then the control unit 40 selects a number of blocks according to the predetermined capacity of the test option, assigns corresponding logical addresses to the selected blocks, and then implements the P/E cycles to test the endurance of the selected blocks. If the test package corresponding to the obtained storage capacity associates more than one test option, the control unit 40 selects one of the test options, selects a number of blocks according to the predetermined capacity of the selected test option, assigns the corresponding logical addresses to the selected blocks, and then implements the P/E cycles to test the endurance of the selected blocks.

It is well known that the memory 200 is usually divided into a number of segments, and each segment includes a number of blocks serving as the smallest programming and erasing unit. In the embodiment, the control unit 40 selects the blocks to be tested equally from each segment so as to satisfy the reliability of the endurance of the whole memory 200, and the selected blocks from all segments are equivalent to the predetermined capacity of the test option. Furthermore, the selected blocks from each segment are continuous blocks, thus the control unit 40 can assign sequential logical addresses to the selected blocks to allow the time for the endurance test of the selected blocks to be reduced.

Since only a part of blocks of the memory 200 is tested, the time for the endurance test of the memory 200 is reduced. As mentioned above in the example, the time for the endurance test of the hard disk is 10 days if all of the 250,000 blocks are tested. But if only 625,000 blocks equivalent to 0.5 megabytes are selected to be tested, the time for the endurance test of the hard disk is nearly 2.5 days. Thus, the time for the endurance test of the hard disk is reduced. However, it is notable that although less time is needed with less blocks to be tested in the endurance test, the minimum tested blocks are limited so as to satisfy the reliability of the endurance of the whole memory 200.

In the embodiment, the electronic device 100 further includes a display unit 50 and an input unit 60. The display unit 50 displays the test options when the test package corresponding to the obtained storage capacity associates two or more test options. The input unit 60 is for a user to select one displayed test option. The control unit 40 further responds to the user input to obtain the corresponding test option selected by the user. In an alternative embodiment, each test option may be assigned with a priority level. In this case, the control unit 40 selects a test option with a highest priority level.

In the embodiment, the electronic device 100 further includes a calculating unit 70, and the calculating unit 70 is configured to calculate the time for the endurance test of the selected blocks.

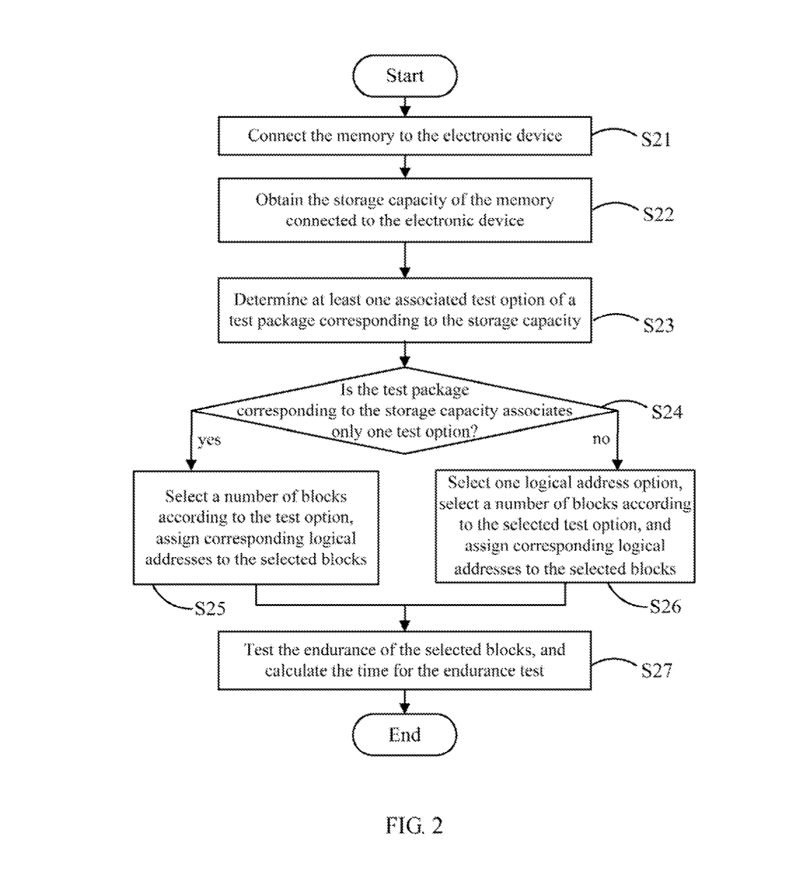

FIG. 2 is a flowchart of a method for endurance test of the memory implemented by the electronic device 100 of FIG. 1 according to an exemplary embodiment.

In step S21, through the interface 10, the memory 200 is connected to the electronic device 100.

In step S22, the obtaining unit 30 obtains the storage capacity of the memory 200 connected to the electronic device 100 via the interface 10.

In step S23, the control unit 40 determines the at least one associated test option of the test package corresponding to the obtained storage capacity stored in the storage unit 20, and the test option defines a predetermined capacity of the associated memory 200 to be tested.

In step S24, the control unit 40 determines whether the test package corresponding to the obtained storage capacity associates only one test option. If yes, the procedure goes to step S25; otherwise, the procedure goes back to step S26.

In step S25, the control unit 40 selects a number of blocks according to the predetermined capacity of the test option, and assigns the corresponding logical addresses to the selected blocks.

In step S26, the control unit 40 responds to the user input through the input unit 60 and obtains one test option selected by the user, selects a number of blocks according to the predetermined capacity of the selected test option, and assigns the corresponding logical addresses to the selected blocks.

In step S27, the control unit 40 tests the endurance of the selected blocks, and the calculating unit 70 calculates the time for the endurance test of the selected blocks.

Although the present disclosure has been described in accordance with the embodiments shown, one of ordinary skill in the art will readily recognize that there could be variations to the embodiments and those variations would be within the spirit and scope of the present disclosure. Accordingly, many modifications may be made by one of ordinary skill in the art without departing from the spirit and scope of the appended claims.

What is claimed is:

1. An electronic device for endurance test of a memory, the memory comprising a plurality of blocks, the electronic device comprising:
an interface to connect the memory to the electronic device;
a storage unit to store a plurality of test packages for different storage capacities of memories and at least one test option associated with each test package, and each test option defining a predetermined capacity of the associated memory to be tested;
an obtaining unit to obtain a storage capacity of the memory connected to the electronic device; and
a control unit to select one of the at least one test option associated with one of the test packages corresponding to the obtained storage capacity, select a plurality of blocks according to the predetermined capacity of the selected test option, assign corresponding logical addresses to the selected blocks, and test the endurance of the selected blocks.

2. The electronic device as described in claim 1, wherein the control unit is further configured to determine the at least one associated test option of the test package corresponding to the obtained storage capacity and then determine whether the test package corresponding to the obtained storage capacity associates only one test option; if the test package corresponding to the obtained storage capacity associates only one test option, the selected test option is the associated test option of the test package corresponding to the obtained storage capacity; if the test package corresponding to the obtained storage capacity associates two or more test options, the control unit selects one test option from the associated test options.

3. The electronic device as described in claim 1, wherein the memory comprises a plurality of segments, and each segment comprises a plurality of blocks; the control unit is configured to select the blocks equally from each segment, and the selected blocks from all segments are equivalent to the predetermined capacity of the test option.

4. The electronic device as described in claim 1, wherein the selected blocks from each segment are continuous blocks; the control unit is configured to assign sequential logical addresses to the selected blocks to allow the time for the endurance test of the selected blocks to be reduced.

5. The electronic device as described in claim 2, further comprising a display unit and an input unit, wherein the display unit is configured to display the test options if the test package corresponding to the obtained storage capacity associates more than one test option; the input unit is for a user to select one displayed test option; and the control unit is configured to responds to the user input to obtain the corresponding test option selected by the user.

6. The electronic device as described in claim 1, wherein each test option is assigned with a priority level, and the control unit is further configured to select a test option with a highest priority level.

7. The electronic device as described in claim 1, further comprising a calculating unit, wherein the calculating unit is configured to calculate a time for the endurance test of the selected blocks.

8. A method for endurance test of a memory applied to an electronic device, the memory comprising a plurality of blocks, method comprising:
connecting the memory to the electronic device;
obtaining a storage capacity of the memory connected to the electronic device;
selecting one test option associated with a test package corresponding to the obtained storage capacity, wherein the electronic device stores a plurality of test packages for different storage capacities of memories and at least one test option associated with each test package, and the test option defining a predetermined capacity of the associated memory to be tested; and
selecting a plurality of blocks according to the predetermined capacity of the selected test option, assigning corresponding logical addresses to the selected blocks, and testing the endurance of the selected blocks.

9. The method as described in claim 8, wherein the step selecting one test option associated with a test package corresponding to the obtained storage capacity further comprising:
determining the at least one associated test option of the test package corresponding to obtained storage capacity;
determining whether the test package corresponding to obtained storage capacity associates only one test option;
selecting one test options from the associated test options if the test package corresponding to obtained storage capacity associates two or more test options.

10. The method as described in claim 9, wherein the step selecting one test option from the associated test options if the test package corresponding to obtained storage capacity associates two or more test options further comprising:
displaying the test options if the test package corresponding to obtained storage capacity associates two or more test options;
responding to a user input to select one test option, and obtaining the corresponding test option selected by the user.

11. The method as described in claim 9, wherein the each test option is assigned with a priority level, and the selected test option from the two or more test options is that with a highest priority level.

12. The method as described in claim 8, wherein the method further comprising:
calculating a time for the endurance test of the selected blocks.
